(19) United States
(12) Patent Application Publication
(10) Pub. No.: US 2025/0192514 A1
(43) Pub. Date: Jun. 12, 2025

(54) TRANSITION TEMPERATURE MONITORING METHOD AND OPTOELECTRONIC LASER DEVICE

(71) Applicants: ams-OSRAM International GmbH, Regensburg (DE); ams International AG, Jona (CH)

(72) Inventors: Joerg Erich SORG, Regensburg (DE); Karolina TRACZYK, Bursins (CH)

(21) Appl. No.: 18/856,068

(22) PCT Filed: Apr. 13, 2023
(86) PCT No.: PCT/EP2023/059737

§ 371 Date: Oct. 11, 2024

(30) Foreign Application Priority Data
Apr. 14, 2022 (DE) 10 2022 109 253.4

(51) Int. Cl. H01S 5/068; H01S 5/22; H01S 5/40

(52) U.S. Cl. CPC H01S 5/06804; H01S 5/06808; H01S 5/22; H01S 5/4031

(57) ABSTRACT

A method of operating a laser device which includes a first and a second laser ridge arranged on a semiconductor substrate adjacent to each other and being thermally coupled. The method includes operating the first laser ridge with a first supply current such that the first laser ridge emits laser light trough a laser facet of the first laser ridge, and while operating the first laser ridge, simultaneously operating the second laser ridge with a second supply current such that the second laser ridge does not emit light trough a laser facet of the second laser ridge. The method further includes determining a voltage drop over the second laser ridge and regulating the first supply current as a function of the voltage drop determined over the second laser ridge.

### RELATED APPLICATIONS

This patent application is a US National Stage application, 35 U.S.C. § 371, of International Application PCT/EP2023/059737, filed Apr. 13, 2023, and claims priority from German patent application DE 10 2022 109 253.4, filed on Apr. 14, 2022, the contents of the above-applications are hereby incorporated by reference in their entirety.

### FIELD

Various aspects of the present disclosure relate to a method for operating an optoelectronic laser device, in particular a laser ridge of the optoelectronic laser device, in dependence on a transition temperature determined in the optoelectronic laser device and in particular in the laser ridge. In addition, aspects of the present disclosure relate to an optoelectronic laser device with integrated monitoring of the transition temperature in the optoelectronic laser device, in particular a laser ridge of the optoelectronic laser device, during its intended use.

### BACKGROUND

Laser emitters such as for example used in laser beam scanning projectors must be operated with a current to emit laser light. Laser operation begins at a characteristic current in the direction of flow, the threshold current. Below this current, the laser emitter emits non-coherent radiation similar to a light-emitting diode, but no laser light. Above the threshold current, the optical output power of the laser emitter is proportional to the impressed current. The wavelength of the light emitted by the laser emitter depends, among other things, on the material/the material system used for the laser emitter, the impressed current, and the temperature, in particular the transition temperature, within the laser emitter. Heating the laser emitter, especially in the area of its active zone, leads to wavelength changes of the emitted laser light. The shift can be about +0.25-0.3 nm/K, whereby the maximum of the radiation shifts towards longer wavelengths when heated by reducing the band gap in the active zone.

To counteract such wavelength changes it is a goal to keep the bandwidth of the emitted light low during the intended use of the laser emitter by stabilising these parameters, in particular by stabilising the temperature. This can for example be done by readjusting the current impressed on the laser emitter so that it emits light with essentially the same wavelength spectrum during its intended use.

Currently, the wavelength shift of a laser emitter is usually determined optically in order to infer the transition temperature in the active zone of the laser emitter. For the optical measurement of the wavelength shift, a spectrometer is usually used to record the wavelength shift during the intended use of the laser emitter. The recorded wavelength shift can then be used to infer the changing transition temperature in the active zone of the laser emitter at a constant impressed current. However, measuring the temperature by optically determining the wavelength shift is slow, expensive and increases the size of the product comprising the laser emitter due to the need for a precise spectrometer.

Another approach is to place a separate temperature sensor in a device comprising the laser emitter. Such temperature sensors however provide the temperature information approximate and averaged, as they are at few milli-meters distance from the laser emitter and cannot differentiate between several laser emitters arranged for example in a pitch in close proximity to each other. In addition, such a separate temperature sensor increases the size of the product comprising the laser emitter.

A temperature shift monitoring can also be performed by a measurement of the light emitting laser's forward voltage itself. The important limitation is that this measurement can be done only while a given laser emitter is not displaying pixels of a non-uniform image. Therefore, there are only small timing gaps (MEMS mirror return or a flyback phase) or constant display conditions (ex. black image) when the lasing emitters can be used for temperature sensing.

Accordingly, aspects of the present disclosure relate to a method for operating a laser emitter that counteracts at least one of the aforementioned problems. Aspects of the present disclosure also relate to a corresponding laser emitter.

### SUMMARY

An optoelectronic laser device as provided can for example be used in a laser beam scanning projector. Laser beam scanning projectors rely on a set of RGB sources and MEMS mirrors, either a pair of mirrors which are swinging along on axis each or a MEMS mirror which swings along two axes to create an image. The RGB laser sources create a single pixel of the display which is then scanned in a 2D pattern to form an image. The optoelectronic laser device can therefore form an RGB laser source comprising a first laser ridge for each of the colours red, green, and blue. In order to achieve a correct white balance/colour balance of the pixel created by the laser device, the amount of light originating from red, green and blue laser ridges should be in a correct proportion between the listed colours and perform at required brightness. During operation and due to the operation of the laser device, each laser ridge may experience a certain temperature drift. The temperature of a given laser ridge may be influenced by parameter as:
Ambient temperature;
Driving conditions, related to the content to be projected (Current amplitude, CW or pulsed operation, timing of current pulses: ON Time, repetition rate, etc.);
content history;
Lasers dies and laser ridges/resonators in direct neighbourhood;
Other heat dissipation components in the neighbourhood of the laser device (e.g. Driver components).

The optoelectronic laser device characteristics and in particular the laser ridges are temperature dependent. As well the threshold as the slope efficiency shows deviations with temperature. Therefore, it can be important to know the actual temperature of the laser ridges. Otherwise, it becomes a gamble to meet the right brightness and colour coordinate for the next pixel to be created by the optoelectronic laser device. During operation of the laser ridges the temperature shifts of the RGB laser ridges should thus be detected and driving conditions should be corrected to ensure correct white balance/colour balance and brightness. One should keep in mind that such temperature sensing should be precise, fast (pixels displayed on the display can be as short as few nanoseconds), and it should represent a small form factor with reduced amount of various components included in the laser device.

In at least one example of the present disclosure, at least one temperature sensing ridge, also called “dummy ridge”, is therefore placed within the array of light emitting ridges in their close proximity (few or tens of micro-meters), on the same semiconductor substrate. The dummy ridge can then be used as a temperature sensor located in close proximity to the light emitting ridges. Such examples can be used simultaneously with the operation of the light emitting ridges, independently on the image content being displayed. A number of configurations can thereby be implemented, such as single or multiple dummy ridges placed on a common semiconductor substrate with single or multiple light emitting ridges.

At least one aspect of the present disclosure relates to an optoelectronic laser device with at least one first laser ridge and at least one second laser ridge, which are arranged adjacent to each other and thermally coupled. The thermal coupling is achieved by a common semiconductor substrate on which the laser ridges are formed. The at least one first laser ridge comprises a laser facet through which laser light is emitted during an intended operation of the at least one first laser ridge, while the at least one second laser ridge is modified and/or is operated, during the intended operation of the at least one first laser ridge, such that an emission of light, in particular laser light, of the at least one second laser ridge is prevented. The at least one second laser ridge can therefore also be called a “dummy ridge”. By means of a voltage detector, the voltage drop over the at least one second laser ridge is determined, which can change due to a heating of the at least one first laser ridge and thus also of the thermally coupled second laser ridge, during operation of the first laser ridge. Depending on the voltage drop or voltage change determined over the at least one second laser ridge, the current impressed on the first laser ridge is readjusted in order to avoid a wavelength shift of the laser light emitted by the at least one first laser ridge.

The thermal coupling ensures that the at least one second laser ridge behaves thermally at least essentially identically to the at least one first laser ridge during operation of the first laser ridge. This is as the at least one dummy ridge is placed in a close proximity to the light emitting ridge, resulting in for example a pair of emitters (dummy ridge +light emitting ridge) on a common semiconductor substrate. The transition temperature in the second laser ridge and thus also the transition temperature in the first laser ridge can be concluded by means of the voltage drop or the voltage change measured over the second laser ridge. One reason for this is that the voltage drop measured over a laser ridge decreases when the transition temperature in the laser ridge increases.

The use of a second laser ridge, arranged in close proximity to the first laser ridge, can have the advantage that the measured voltage drop or the measured voltage change over the second laser ridge can be determined during operation of the first laser ridge by means of an independent measurement. The measurement over the at least one second laser ridge can in particular be carried out independent of an emission of light of the at least one second laser ridge as the at least one second laser ridge may either be modified, such that an emission of light during operation of the at least one second laser ridge is prevented or as the at least one second laser ridge may be operated with a current below the threshold of the at least one second laser ridge and thus does not emit light. An independent measurement of the transition temperature within the at least one first laser ridge (and thus the voltage drop or the measured voltage change over the first laser ridge) can on the other hand be difficult, as the at least one first laser ridge may as intended be operated in a high-frequency pulse mode to emit laser light of a specific wavelength in a desired high frequency, and may thus be dependent on several parameters. As the at least one second laser ridge can however be operated with an independent current, independent of an emission of light of the at least one second laser ridge, but “interacts” thermally with the first laser ridge via the thermal coupling, a temperature shift in the at least one first laser ridge can be concluded by means of the voltage drop or the voltage change measured over the second laser ridge in a way independent of the high-frequency pulse mode the at least one first laser ridge is operated with.

Due to the independent measurement, the measurement of the voltage drop over the second laser ridge can be easily calibrated and the measurement accuracy of the transition temperature in the second laser ridge and thus also in the first laser ridge can be increased. When measuring the voltage drop over the first laser ridge, on the other hand, an additional circuit for measuring the voltage drop, in a high-frequency pulse mode of the first laser ridge, would cause problems and, due to the dependence on the load current, calibration of the measurement would be more difficult.

Contrary to determining the wavelength shift and thus the increase of the transition temperature of a laser ridge optically by means of a spectrometer, the measurement of the transition temperature via the voltage drop over the second laser ridge is a direct and thus more accurate measurement method. In particular, in the case of a current impressed on the laser ridge with a constant load current below the laser threshold, e.g., an essentially load-free state of the laser ridge, a particularly accurate and interference-free measurement of the voltage drop, or change in the voltage drop, over the laser ridge can be made with a changing transition temperature within the laser ridge. In addition, a calibration of such a measurement can be carried out particularly easily.

Advantages of aspects or examples of the present disclosure can for example be:
high precision and speed of a temperature measurement;
small form factor of the optoelectronic laser device; and
freedom to choose periods of temperature monitoring, independently of image content being displayed, as dummy ridge(s) do not output light and do not interfere optically with the other laser ridges of the optoelectronic laser device.

According to at least one embodiment, a method for operating an optoelectronic laser device comprises the steps of:
providing the optoelectronic laser device comprising at least one first and at least one second laser ridge arranged on a semiconductor substrate adjacent to each other and being thermally coupled;
operating the at least one first laser ridge with a first supply current such that the at least one first laser ridge emits laser light trough a laser facet of the at least one first laser ridge;
while operating the at least one first laser ridge, simultaneously operating the at least one second laser ridge with a second supply current such that the at least one second laser ridge does not emit light, in particular laser light, through a laser facet of the at least one second laser ridge;
determining a voltage drop over the at least one second laser ridge; and
regulating the first supply current as a function of the voltage drop determined over the at least one second laser ridge.

The at least one first laser ridge is operated with a first supply current such that laser light of a desired wavelength is emitted through a laser facet of the at least one first laser ridge. The at least one second laser ridge is on the other hand modified and/or is operated, during operation of the at least one first laser ridge, such that an emission of light of the at least one second laser ridge is prevented. An emission of light of the at least one second laser ridge can for example be prevented by modifying the at least one second laser ridge in such that light is not coupled out of the laser ridge or by operating the at least one laser ridge with a supply current below the laser threshold of the at least one second laser ridge. An outcoupling of light out of the at least one second laser ridge can for example be prevented by etching one or more interruptions into the laser ridge which are for example coated with a dielectric material.

According to at least one embodiment, the at least one first laser ridge is operated at a higher current than the at least one second laser ridge during the step of determining the voltage drop over the at least one second laser ridge. In particular, the first laser ridge is operated at a current that is at least a factor of 50 higher than the current impressed on the at least one second laser ridge. For example, the at least one second laser ridge can be operated with approximately 1% of the first supply current, which may correspond to a value just below the laser threshold. The current applied to the at least one second laser ridge, namely the second supply current, can be selected below the laser threshold in such a way that no light, in particular no laser light, is emitted and there is no thermal load on the at least one second laser ridge. A particularly low current applied to the at least one second laser ridge also leads in particular to a power loss of the optoelectronic laser device being kept as low as possible. The current applied to the at least one second laser ridge can therefore chosen to be as low as possible. The at least one second laser ridge can however also be biased above the lasing threshold (depending on the best sensitivity of the U/I characteristics).

When the measurement of the voltage drop over the at least one second laser ridge is performed at a working point above the threshold of the second laser ridge, the at least one second laser ridge may comprise a working resonator. To ensure the at least one second laser ridge does however not emit light, end mirrors of the resonator can be modified such that they are perpendicular to the main extension of the resonator. If the at least one second laser ridge is however operated beneath the threshold a working resonator can be dispensed.

According to at least one embodiment, the step of determining the voltage drop over the at least one second laser ridge comprises determining the transition temperature of the at least one first laser ridge, in particular based on the determined voltage drop over the at least one second laser ridge during the intended operation of the first laser ridge.

The intended operation of the first laser ridge can cause the laser ridge to heat up over time due to the first supply current impressed on the first laser ridge. With a constant impressed current, this leads to the laser ridges emitting laser light of a different, in particular longer, wavelength in correlation with the heating. By determining the transition temperature within the first laser ridges, the current impressed on the first laser ridges can be readjusted in the event of a possible wavelength shift, so that they emit light with essentially the same wavelength spectrum despite heating during their intended use.

The temperature information determined over the at least one second laser ridge in particular enables a user of the optoelectronic laser device to derive a distinctive information of the temperature state of other ridges of the laser device. When having a plurality of first laser ridges and a plurality of second laser ridges, the second laser ridges each being associated to a first laser ridge, then the temperature state of each first laser ridge can be determined quite precisely. This granularity allows to estimate a correction signal for each light emitting ridge separately.

The regulating signal provided to the at least one first laser ridge may include a threshold current correction, and/or a slope efficiency correction, and/or a slope linearity correction. Such types of corrections can for example be performed independently by a laser driver circuit. The threshold current correction accounts for an exponential dependence of the threshold current vs. the temperature. The slope efficiency correction includes a change of the slope of the LI characteristics as well as a deviation from the linear behaviour of the LI characteristics above the laser threshold current. At the same time a calibration at known temperature conditions can be performed to detect any ageing effects within the laser device, as they may influence the temperature sensing and laser driving correction algorithm. Due to laser ageing the laser characteristics (and so the measured data point) can for example shift in the direction as in case of a higher operation temperature (increase if the threshold current, decrease of slope efficiency etc.).

The deviations in the U/I characteristic of the dummy ridges, which are intended to be used for the temperature measurement can be tiny. Additionally, the voltage drop over the dummy ridges may be measured on a high frequency as it need to follow the operation conditions of the light emitting ridges which can be operated with frequencies down to single digit ns pulsed. Therefore, the integration time to extract a clean signal can be limited. This problem can be improved by an improved signal to noise ration. It can therefore be advantageous to connect several second laser ridges in a serial connection to determine a better signal/voltage drop value. The first supply current can then be readjusted as a function of the integrated voltage value. Alternatively, the mean value or the average of the determined voltage values can be determined over the same period of time, from the beginning of an emitted light pulse to the end of an emitted light pulse, and the first supply current can be readjusted as a function of the averaged voltage value.

In some aspects, the at least one first laser ridge is operated in pulsed mode, in particular in high-frequency pulsed mode. For example, the first laser ridge can be configured to provide uniform, high-frequency modulated laser light (flood illumination).

In some aspects, the at least one second laser ridge is identical in construction to the at least one first laser ridge. The term “identical” can be understood in particular as meaning that the at least one first laser ridge and the at least one second laser ridge are manufactured using the same technology and the same material system, comprise the same size and dimensions, and, in particular, have been grown on the same semiconductor substrate.

According to at least one embodiment, the at least one second laser ridge is operated in pulsed mode. By this, the power consumption of the system and a self-heating of the at least one second laser ridge can be reduced. The at least one second laser ridge can however also be operated by a constant current source (DC mode). For example, the constant current source can be formed by a current mirror which is configured to apply a desired current to the at least one second laser ridge.

According to at least one embodiment, the at least one second laser ridge is operated in reverse direction. The second supply current will thus relate to a reverse current applied to the at least one second laser ridge. Operating the at least one second laser ridge in reverse direction leads to the at least one second laser ridge not emitting laser light while being operated. The voltage measurement/determining of the voltage drop over the at least one second laser ridge while operating the at least one first laser ridge can thus be done in reverse direction. The temperature characteristic of the at least one second laser ridge will thereby stay the same or will be similar to the temperature characteristic of the at least one first laser ridge, such that a transition temperature in the at least one first laser ridge can be concluded via a voltage drop over the at least one second laser ridge while the at least one second laser ridge is operated in reverse direction and won't emit any light.

In some aspects, no additional function is assigned to the at least one second laser ridge and it is only used to determine a voltage drop at an impressed current. Using the at least one second laser ridge exclusively for temperature sensing, they do not display light. It can however also be conceivable that the at least one second laser ridge is—while the at least one first laser ridge does not emit laser light—operated such that laser light is emitted trough a laser facet of the at least one second laser ridge.

An optoelectronic laser device, in particular with integrated monitoring of the transition temperature in the optoelectronic laser device during its intended use, comprises at least one first laser ridge and at least one second laser ridge arranged adjacent to each other on a semiconductor substrate and being thermally coupled. The at least one first laser ridge is configured to emit laser light through a laser facet of the at least one first laser ridge when being operated, while the at least one second laser ridge is modified in such that it does not emit light when being operated.

In some aspects, the modification of the at least one second laser ridge correlates to at least one interruption in the at least one second laser ridge and in particular in a resonator of the at least one second laser ridge, the at least one interruption being coated with a dielectric material.

In some aspects, the at least one second laser ridge is arranged at a distance of at most 50 μm from the at least one first laser ridge on the semiconductor substrate. This short distance and a thermal coupling via the common semiconductor substrate ensure that the at least one second laser ridge behaves at least substantially identically to the at least one first laser ridge.

The at least one second laser ridge can be placed in parallel to the at least one first laser ridge, but can also be placed with a different orientation, shape and pad placement independent from the light emitting ridge structure. This can bring an important advantage of high freedom in the design of such structure as well as flexibility in defining a pads placement.

According to at least one embodiment, the at least one first laser ridge and the at least one second laser ridge have a common potential. In particular, the at least one first laser ridge and the at least one second laser ridge have a common cathode connection. This common cathode connection can serve on the one hand for thermal coupling and on the other hand enables simplified conductor routing.

According to at least one embodiment, the at least one first laser ridge, the at least one second laser ridge and the common semiconductor substrate together form an EEL (edge-emitting laser), which can be designed as a multi-channel component each laser ridge defining a “channel” of the component.

In some aspects, the at least one first laser ridge and the at least one second laser ridge each comprise a resonator with different lengths. For EELs, end mirrors of a laser ridge, one of them forming a laser facet of the laser ridge, can for example be generated by a scribe and break process. This means that the outline of the optoelectronic laser device may define the length of the laser ridges and thus of a resonator of the laser ridges. In case of etched facets where for instance dry etching processes are combined with wet etching process to generate the end facets, additional design freedom is gained as the length of particularly the dummy ridge can be freely chosen in a wide range.

In some aspects, the optoelectronic laser device comprises a plurality of first laser ridges and a plurality of second laser ridges each of the plurality of second laser ridges being associated with at least one of the plurality of first laser ridges. The first laser ridges are configured to emit laser light through a laser facet of the first laser ridges when being operated, and the second laser ridges are each modified in such that they do not emit light when being operated. At least a number of the plurality of second laser ridges can thereby for example be connected in series. This can be advantageous to determine a better signal/voltage drop value.

In some aspects, the optoelectronic laser device comprises an integrated circuit (IC) configured to provide a first supply current, in particular current pulse, to the at least one first laser ridge, and a second supply current to the at least one second laser ridge. A dedicated driver IC can thus be used for driving the light emitting ridges and at the same time drive the temperature sensing ridges. In this way by re-using already existing functionality of the driver IC one can perform temperature sensing, resulting in lower power consumption. If the driver IC drives the first and second laser ridges each in a pulsed mode, power consumption can further be decreased and the influence of self-heating effect in the laser device can be decreased as well.

In some aspects, the second supply current is a current below the laser threshold of the at least one second laser ridge. The at least one second laser ridge may thus not emit light when being operated.

In some aspects, the optoelectronic laser device comprises a voltage detector configured to detect a voltage drop over the at least one second laser ridge. The integrated circuit can for example be configured to provide the first supply current as a function of the voltage drop determined over the at least one second laser ridge to compensate a potential wavelength shift of the laser light emitted by the at least one first laser ridge due to a changing transition temperature of the first laser ridge.

### BRIEF DESCRIPTION OF THE DRAWINGS

In the following, embodiments of the present disclosure are explained in more detail with reference to the accompanying drawings. They show, schematically in each case,

FIG. 1 an optoelectronic laser device according to some aspects of the present disclosure;

FIGS. 2 and 3 further embodiments of an optoelectronic laser device according to some aspects of the present disclosure;

FIG. 4 a detailed view of an embodiment of an optoelectronic laser device according to some aspects of the present disclosure; and

FIG. 5 steps of a method for operating an optoelectronic laser device according to some aspects of the present disclosure.

### DETAILED DESCRIPTION

The following embodiments and examples show various aspects and their combinations according to the present disclosure. The embodiments and examples are not always to scale. Likewise, various elements may be shown enlarged or reduced in size to highlight individual aspects. It is understood that the individual aspects and features of the embodiments and examples shown in the figures may be readily combined with each other without affecting principles of the present disclosure. Some aspects have a regular structure or shape. It should be noted that minor deviations from the ideal shape may occur in practice, but without contradicting concepts of the various aspects of the present disclosure.

In addition, the individual figures, features and aspects are not necessarily shown in the correct size, nor do the proportions between the individual elements have to be fundamentally correct. Some aspects and features are emphasised by showing them enlarged. However, terms such as “above”, “over”, “below”, “under”, “larger”, “smaller” and the like are correctly represented in relation to the elements in the figures. Thus, it is possible to derive such relationships between the elements from the figures.

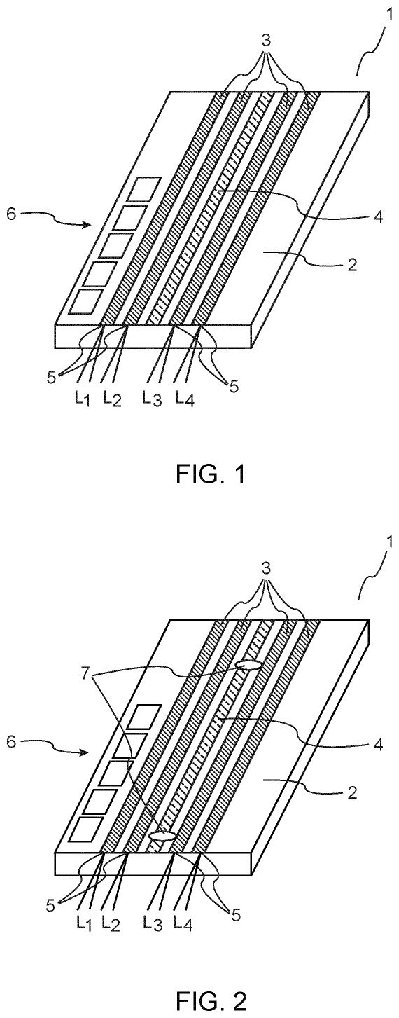

FIG. 1 shows an optoelectronic laser device 1 according to some aspects of the present disclosure. The optoelectronic laser device 1 comprises a semiconductor substrate 2 and a plurality of laser ridges 3, 4 arranged on the semiconductor substrate 2. The optoelectronic laser device 1 comprises a plurality of first laser ridges 3, as well as one second laser ridge 4, wherein the number of first and second laser ridges is understood to be exemplary and can vary. The first and the second laser ridges 3, 4 are identical in construction and are thermally coupled via the semiconductor substrate 2. Due to the thermal coupling, a heating of the first laser ridges 3 during an intended operation of the same leads to an essentially identical heating as of the second laser ridge 4.

The first laser ridges 3 and the second laser ridge 4 each comprise a resonator, and are, when powered with a respective supply current, configured to each emit laser light through a laser facet 5. The first laser ridges 3 are in particular configured to emit laser light L₁₋₄ of a desired wavelength when operated with a first supply current. The second laser ridge 4 is on the other hand operated with a second supply current below the laser threshold of the second laser ridge such that no light, and in particular no laser light, is emitted. The second laser ridge 4 can however be used as a so called dummy ridge, to measure a voltage drop over it and by this to determine a transition temperature or at least a change of the transition temperature in the second laser ridge 4.

When applying a current below the laser threshold to the second laser ridge 4, a voltage drop over the second laser ridge 4 can be determined by means of an essentially load-independent measurement. The voltage drop over the second laser ridge 4, or in particular a voltage change dropping over the second laser ridge 4, can be used to infer a temperature change, in particular a change in the transition temperature, in the second laser ridge 4 at a constant current level impressed on the second laser ridge 4. By means of the transition temperature determined in the second laser ridge 4, it is then possible to infer the transition temperature in the first laser ridges 3, at least in the first laser ridges 3 in close proximity to the second laser ridge 4, on the basis of the thermal coupling. Due to the load-independent measurement, the measurement of the voltage drop over the second laser ridge 4 can be easily calibrated and the measurement accuracy of the transition temperature in the second laser ridge 4 and thus also in the first laser ridges 3 can be increased.

By means of a control circuit (not shown here) connected to the first laser ridges 3 via pads 6, the first laser ridges 3 can be controlled as a function of the voltage drop or transition temperature determined via the second laser ridge 4. Accordingly, the first supply current can be controlled or readjusted as a function of the voltage drop determined via the second laser ridge 4 in such a way that the first laser ridges 3 each emit substantially light with the same wavelength spectrum despite heating during their intended use. A wavelength shift of the light emitted by the first laser ridges 3 due to their heating can thus be prevented.

The second laser ridge 4 is in the example shown arranged between the first laser ridges 3 and arranged in parallel to them, it can however also be placed with a different orientation.

FIG. 2 shows a further embodiment of an optoelectronic laser device 1. In contrast to the embodiment shown in FIG. 1, the resonator of the second laser ridge 4 comprises interruptions 7 coated with a dielectric material. This results in two end mirrors of the resonator oriented perpendicular to the main extension of the resonator preventing an emission of light even if the second laser ridge 4 is operated with a supply current greater than the threshold current of the second laser ridge.

For most EEL (Edge Emitting Lasers) and mirrors of the resonator of a laser ridge and thus the laser facet of a laser ridge are generated by a scribe and break processes. This means that the outline of the laser device would define the length of the laser ridges. As shown in the figure this can for example be the case for the first laser ridges with its laser facets 5 located close to the edge of the semiconductor substrate 2 and the laser ridges extending along the whole length of the semiconductor substrate 2. To generate the interruptions 7 within the second laser ridge 4, dry etching processes to generate the end facets/mirrors as for the first laser ridges 3 can be combined with wet etching processes to generate the interruptions 7 within the actual resonator of the second laser ridge. The second laser ridge 4 can thus be divided into portions only some or all of which can later be used as dummy ridges to measure a voltage drop over them to determine a transition temperature in the first laser ridges 3. The length of the dummy ridge over which a voltage drop is later measured can be chosen quite freely and in a wide range such that additional design freedom is gained.

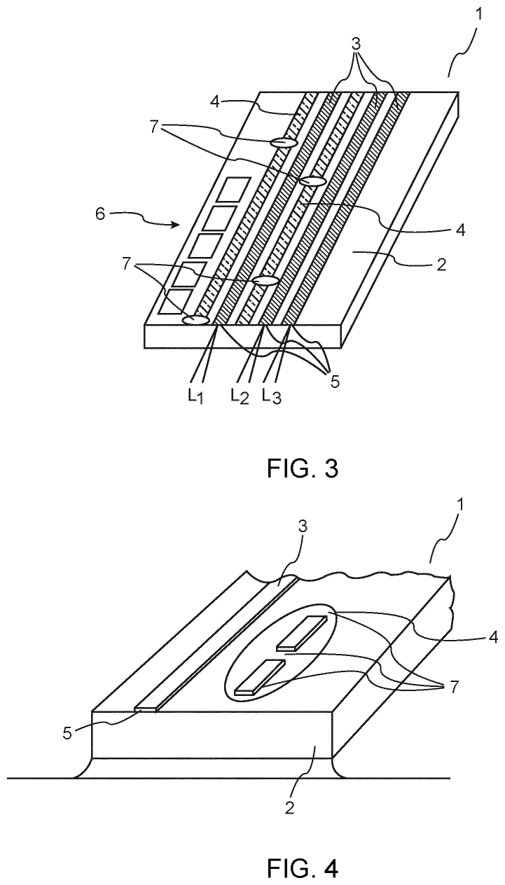

FIG. 3 shows a further embodiment of an optoelectronic laser device 1 indicating that the laser device 1 can comprise more than one second laser ridge 4. In the shown example the optoelectronic laser device 1 comprises two second laser ridges 4 arranged on the semiconductor substrate 2. Each a second laser ridge 4 can be associated to at least one first laser ridge 3 such that via the associated second laser ridge 4 a transition temperature in the first laser ridges 3 can be determined even more accurate. Here it is exemplary possibilities of combinations are shown how second laser ridges 4 can be associated to first laser ridges 3. There can be a one on one association, a two on one association where one second laser ridge is arranged between two first laser ridges or a two on one association where one second laser ridge is arranged next to two or even more first laser ridges 3.

It is also indicated by the figure that the coated interruptions 7 can be located anywhere along the second laser ridge 4 and thus define different portions of the second laser ridge 4. This is shown in even more detail in FIG. 4, showing the second laser ridge 4 being divided into two portions by interruptions 7. The two remaining portions can thereby each be used to measure a voltage drop over them to determine the transition temperature in the neighbouring first laser ridge 3. The two portions can therefore form sub dummy ridges via which the transition temperature in the neighbouring first laser ridge 3 can be determined. These sub dummy ridges can for example be connected in series to determine a better signal/voltage drop value.

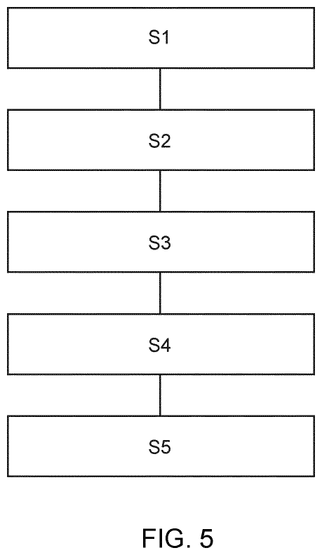

FIG. 5 shows method steps of a method for operating an optoelectronic laser device according to some aspects of the present disclosure. In a first step S1, an optoelectronic laser device is provided the laser device comprising at least one first and at least one second laser ridge arranged on a semiconductor substrate adjacent to each other and being thermally coupled. In a second step S2, the at least one first laser ridge is operated with a first supply current such that the at least one first laser ridge emits laser light through a laser facet of the at least one first laser ridge. Simultaneously with step S2, in a third step S3 the at least one second laser ridge is operated with a second supply current such that the at least one second laser ridge does however not emit light trough a laser facet of the at least one second laser ridge. Simultaneously with the second and the third step S2, S3, in a fourth step a voltage drop is determined over the at least one second laser ridge to conclude on a transition temperature within the second laser ridge and du to the thermal coupling also within the first laser ridge. As a function of the voltage drop determined via the at least one second laser ridge, the supply current of the at least one first laser ridge is then readjusted in a fifth step S5 so that it emits substantially light with the same wavelength spectrum despite heating during its intended use.

### REFERENCE LIST

1 optoelectronic laser device
2 semiconductor substrate
3 first laser ridge
4 second laser ridge
5 laser facet
6 pad
7 interruption
10 L₁₋₄ laser light
S1-S5 steps

What is claimed is:

1. A method of operating an optoelectronic laser device comprising:
providing the optoelectronic laser device comprising at least one first and at least one second laser ridge arranged on a semiconductor substrate adjacent to each other and being thermally coupled;
operating the at least one first laser ridge with a first supply current such that the at least one first laser ridge emits laser light through a laser facet of the at least one first laser ridge;
while operating the at least one first laser ridge, simultaneously operating the at least one second laser ridge with a second supply current such that the at least one second laser ridge does not emit light trough a laser facet of the at least one second laser ridge;
determining a voltage drop over the at least one second laser ridge; and
regulating the first supply current as a function of the voltage drop determined over the at least one second laser ridge;
wherein the first supply current is higher than the second supply current during the determining of a voltage drop over the at least one second laser ridge.

2. The method of claim 1, wherein determining the voltage drop over the at least one second laser ridge comprises determining the transition temperature of the at least one first laser ridge based on the determined voltage drop.

3. The method according to claim 1, wherein the at least one first laser ridge is operated in pulsed mode.

4. The method according to claim 1, wherein the second supply current is below the laser threshold of the at least one second laser ridge.

5. The method according to claim 1, wherein the at least one second laser ridge is identical in construction to the at least one first laser ridge.

6. The method according to claim 1, wherein an emission of light trough the laser facet of the at least one second laser ridge is blocked blocked by an interruption within the at least one second laser ridge coated with a dielectric material.

7. The method according to claim 1, wherein the at least one second laser ridge is operated in reverse direction.

8. An optoelectronic laser device with integrated monitoring of the transition temperature in the optoelectronic laser device during its intended use, comprising:
at least one first laser ridge and at least one second laser ridge arranged adjacent to each other on a semiconductor substrate and being thermally coupled,
an integrated circuit configured to provide a first supply current to the at least one first laser ridge, and a second supply current to the at least one second laser ridge, and
a voltage detector configured to detect a voltage drop over the at least one second laser ridge,
wherein the at least one first laser ridge is configured to emit laser light through a laser facet of the at least one first laser ridge when being operated with the first supply current,
wherein the at least one second laser ridge is modified so that it does not emit light when being operated with the second supply current, and
wherein the integrated circuit is configured to provide the first supply current to the at least one first laser ridge that is higher than the second supply current during a time when the voltage detector detects a voltage drop over the at least one second laser ridge.

9. The optoelectronic laser device according to claim 8, wherein the at least one second laser ridge comprises an interruption coated with a dielectric material.

10. The optoelectronic laser device according to claim 8, wherein the at least one second laser ridge is arranged at a distance of at most 50 μm from the at least one first laser ridge on the carrier substrate.

11. The optoelectronic laser device according to claim 8, wherein the at least one first laser ridge and the at least one second laser ridge each comprise a resonator with a different length.

12. The optoelectronic laser device according to claim 8, the at least one first laser ridge comprising a plurality of first laser ridges and the at least one second laser ridge comprising a plurality of second laser ridges each of the plurality of second laser ridges being associated with at least one of the plurality of first laser ridges,
wherein the plurality of the first laser ridges are each configured to emit laser light through its respective laser facet when being operated, and
wherein the plurality of the second laser ridges are each configured to not emit light when being operated.

13. (canceled)

14. The optoelectronic laser device according to claim 8, wherein the second supply current is a current below the laser threshold of the at least one second laser ridge.

15. (canceled)

16. The optoelectronic laser device according to claim 8, wherein the integrated circuit is configured to provide the first supply current as a function of the voltage drop detected over the at least one second laser ridge.

17. The optoelectronic laser device according to claim 12, wherein two or more of the plurality of second laser ridges is connected in series.
